(19) United States
(12) Patent Application Publication
(10) Pub. No.: US 2014/0103996 A1
(43) Pub. Date: Apr. 17, 2014

(54) FRONT-END AMPLIFIER

(71) Applicants: Kenichi Horiguchi, Tokyo (JP); Katsuya Kato, Tokyo (JP); Kenji Mukai, Tokyo (JP); Naoko Matsunaga, Tokyo (JP); Morishige Hieda, Tokyo (JP); Kazutomi Mori, Tokyo (JP)

(72) Inventors: Kenichi Horiguchi, Tokyo (JP); Katsuya Kato, Tokyo (JP); Kenji Mukai, Tokyo (JP); Naoko Matsunaga, Tokyo (JP); Morishige Hieda, Tokyo (JP); Kazutomi Mori, Tokyo (JP)

(73) Assignee: Mitsubishi Electric Corporation, Tokyo (JP)

(21) Appl. No.: 14/118,380

(22) PCT Filed: Aug. 24, 2012
(86) PCT No.: PCT/JP12/71422

§ 371 Date: Nov. 18, 2013

(30) Foreign Application Priority Data
Oct. 13, 2011 (JP) 2011-225746

(51) Int. Cl. H03F 1/52; H03F 3/24

(52) U.S. Cl. CPC H03F 1/52; H03F 3/24
USPC 330/127

(57) ABSTRACT

A front-end amplifier has an impedance detector that detects an impedance seen looking into an antenna side from a power amplifier from a radio-frequency signal output from the power amplifier and a radio-frequency signal reflected from the antenna, in which a control circuit decides on whether the impedance detected by the impedance detector belongs to a specific region or not, and controls, if the impedance belongs to the specific region, at least one of the bias condition of the power amplifier and the impedance of a variable-matching circuit.

### TECHNICAL FIELD

The present invention relates to a front-end amplifier that amplifies a modulating signal which is an input signal, and that radiates the modulating signal after the amplification into space from an antenna.

### BACKGROUND ART

FIG. 12 is a diagram showing a configuration of a conventional front-end amplifier disclosed in Non-Patent Document 1 mentioned below.

In the conventional front-end amplifier, a radio-frequency signal input via an RF input terminal 101 is supplied to a power amplifier 102, and the power amplifier 102 amplifies the radio-frequency signal which is the input signal.

The radio-frequency signal amplified by the power amplifier 102 is supplied to an antenna 104 connected to an RF output terminal 103, and the antenna 104 emits the radio-frequency signal after the amplification into space.

The power amplifier 102 has its gate or base side connected to a bias circuit 105 that supplies DC voltage and current, and its drain or collector side to a DC/DC converter 106 that supplies DC voltage and current, and the bias circuit 105 and DC/DC converter 106 control a bias condition of the power amplifier 102.

In the conventional front-end amplifier, an isolator 107 is connected between the power amplifier 102 and the antenna 104 to prevent characteristic alterations of the power amplifier 102 due to an impedance variation of the antenna 104 or to prevent damages of the power amplifier 102.

The isolator 107 connected maintains the load impedance seen looking into the antenna 104 side from the power amplifier 102 at a fixed value.

### PRIOR ART DOCUMENT

### Non-Patent Document

Non-Patent Document 1: Toshio NOJIMA and Yasushi YAMAO, “RF Circuits for Mobile Communication Systems”, The Institute of Electronics, Information and Communication Engineers of Japan, pp. 49-50, 2007.

### DISCLOSURE OF THE INVENTION

### Problems to be Solved by the Invention

With the foregoing configuration, the conventional front-end amplifier can maintain the load impedance seen looking into the antenna 104 side from the power amplifier 102. Accordingly, it can prevent the characteristic alterations of the power amplifier 102 due to the impedance variation of the antenna 104, and prevent the destruction of the power amplifier 102. However, the isolator 107 connected between the power amplifier 102 and the antenna 104 presents problems of causing a power loss of the radio-frequency signal, and of increasing the circuit size and cost.

The present invention is implemented to solve the foregoing problems. Therefore it is an object of the present invention to provide a front-end amplifier capable of preventing the characteristic alterations of the power amplifier and the destruction of the power amplifier without connecting the isolator between the power amplifier and the antenna.

### Means for Solving the Problems

A front-end amplifier in accordance with the present invention comprises a power amplifier that amplifies a radio-frequency signal which is an input signal, and supplies the radio-frequency signal after amplification to an antenna; and an impedance detecting unit that detects an impedance seen looking into the antenna side from the power amplifier from the radio-frequency signal output from the power amplifier and from a radio-frequency signal reflected from the antenna, wherein a control unit decides on whether the impedance detected by the impedance detecting unit, at least one of phase and amplitude of the impedance, belongs to a specific region which is an area with a preset range or not, and controls, if the impedance belongs to the specific region, a bias condition of the power amplifier.

### Advantages of the Invention

According to the present invention, it is configured in such a manner that it comprises the power amplifier that amplifies the radio-frequency signal which is the input signal, and supplies the radio-frequency signal after the amplification to an antenna, and the impedance detecting unit that detects the impedance seen looking into the antenna side from the power amplifier from the radio-frequency signal output from the power amplifier and from the radio-frequency signal reflected from the antenna, wherein the control unit decides on whether the impedance detected by the impedance detecting unit, at least one of the phase and amplitude of the impedance, belongs to the specific region which is an area with a preset range or not, and controls, if the impedance belongs to the specific region, the bias condition of the power amplifier. Accordingly, it offers an advantage of being able to prevent the characteristic alterations of the power amplifier or the destruction of the power amplifier without connecting the isolator between the power amplifier and the antenna.

### BRIEF DESCRIPTION OF THE DRAWINGS

FIG. 1 is a block diagram showing a configuration of a front-end amplifier of an embodiment 1 in accordance with the present invention;

FIG. 2 is a Smith chart showing a specific load impedance;

FIG. 3 is a Smith chart showing a load impedance in a specific phase range;

FIG. 4 is a Smith chart showing the load impedance in a specific amplitude range;

FIG. 5 is a block diagram showing a configuration of a front-end amplifier of an embodiment 2 in accordance with the present invention;

FIG. 6 is a diagram illustrating instantaneous amplitude detected by an instantaneous amplitude detector 21 and peak voltages retained by a peak-hold circuit 22;

FIG. 7 is a block diagram showing a configuration of a front-end amplifier of an embodiment 3 in accordance with the present invention;

FIG. 8 is a block diagram showing a configuration of a front-end amplifier of an embodiment 4 in accordance with the present invention;

FIG. 9 is a block diagram showing a configuration of a front-end amplifier of an embodiment 5 in accordance with the present invention;

FIG. 10 is a block diagram showing a configuration of a front-end amplifier of an embodiment 6 in accordance with the present invention;

FIG. 11 is a block diagram showing a configuration of a front-end amplifier of an embodiment 7 in accordance with the present invention; and

FIG. 12 is a block diagram showing a configuration of a conventional front-end amplifier disclosed in the Non-Patent Document 1.

### BEST MODE FOR CARRYING OUT THE INVENTION

The best mode for carrying out the invention will now be described with reference to the accompanying drawings to explain the present invention in more detail.

### Embodiment 1

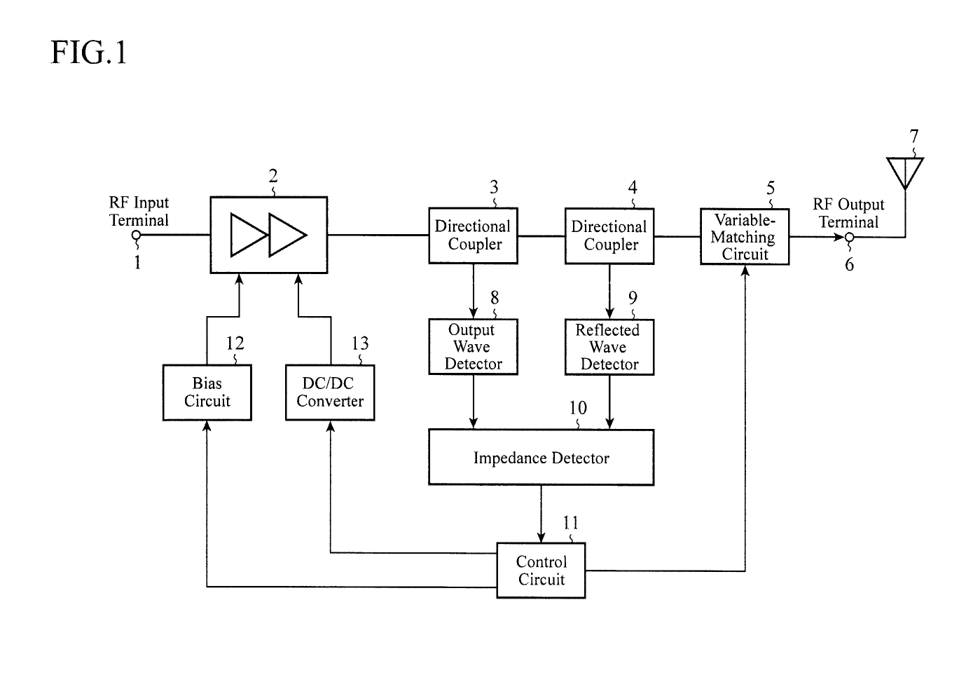

FIG. 1 is a block diagram showing a configuration of a front-end amplifier of an embodiment 1 in accordance with the present invention.

In FIG. 1, an RF input terminal 1 is a terminal for inputting a radio-frequency signal.

A power amplifier 2 is a device that amplifies the radio-frequency signal input via the RF input terminal 1, and outputs the radio-frequency signal after the amplification.

A directional coupler 3 is a device that extracts a part of the radio-frequency signal output from the power amplifier 2, and supplies the part of the radio-frequency signal to an output wave detector 8.

A directional coupler 4 is a device that extracts, from the radio-frequency signal which is supplied from an RF output terminal 6 to an antenna 7, a part of the radio-frequency signal which is reflected and returned from the antenna 7, and that supplies the part of the radio-frequency signal to a reflected wave detector 9.

A variable-matching circuit 5 is a device that is connected across the directional coupler 4 and the RF output terminal 6, and carries out impedance matching between the power amplifier 2 and the antenna 7.

The output wave detector 8 is a device that detects the output wave which is the radio-frequency signal supplied from the directional coupler 3.

The reflected wave detector 9 is a device that detects the reflected wave which is the radio-frequency signal supplied from the directional coupler 4.

An impedance detector 10 is a device that detects the load impedance seen looking into the antenna 7 side from the power amplifier 2 from the output wave detected by the output wave detector 8 and from the reflected wave detected by the reflected wave detector 9.

Incidentally, the directional couplers 3 and 4, the output wave detector 8, the reflected wave detector 9 and the impedance detector 10 constitute an impedance detecting unit.

A control circuit 11 is a circuit that decides on whether the load impedance detected by the impedance detector 10 belongs to a specific region (an area in which the phase and amplitude are set in advance) or not, and that carries out, if the load impedance belongs to the specific region, at least one of the control of a bias condition (such as control of an idle current or power supply voltage) of the power amplifier 2 and the control of the impedance of the variable-matching circuit 5.

A bias circuit 12 is a circuit that controls the idle current of the power amplifier 2 by adjusting the DC voltage and current supplied to the gate or base of the power amplifier 2 under the instruction of the control circuit 11.

A DC/DC: converter 13 is a circuit that controls the power supply voltage to the power amplifier 2 by adjusting the DC voltage and current supplied to the drain or collector of the power amplifier 2 under the instruction of the control circuit 11.

Incidentally, the control circuit 11, the bias circuit 12 and the DC/DC converter 13 constitute a control unit.

Next, the operation will be described.

The radio-frequency signal input to the RF input terminal 1 is supplied to the power amplifier 2, and the power amplifier 2 amplifies the radio-frequency signal which is the input signal.

The radio-frequency signal amplified by the power amplifier 2 is supplied to the antenna 7 connected to the RF output terminal 6, and is emitted into space from the antenna 7.

On this occasion, the impedance of the antenna 7 is not always constant, but varies as a user approaches or touches the antenna 7, for example.

Although it is ideal that the whole radio-frequency signal supplied from the RF output terminal 6 to the antenna 7 is emitted into the space, a part of the radio-frequency signal is reflected from the antenna 7 owing to a variation in the impedance of the antenna 7. The amount of the radio-frequency signal reflected relates to the amount of the variation in the impedance.

To prevent characteristic alterations or destruction of the power amplifier 2 even if the impedance of the antenna 7 varies, the present embodiment 1 executes the following processing.

When the power amplifier 2 outputs the radio-frequency signal after the amplification, the directional coupler 3 extracts a part of the radio-frequency signal, and supplies the part of the radio-frequency signal to the output wave detector 8.

The directional coupler 4 extracts a part of the radio-frequency signal reflected and returned from the antenna 7 from the radio-frequency signal supplied from the RF output terminal 6 to the antenna 7, and supplies the part of the radio-frequency signal to the reflected wave detector 9.

The output wave detector 8, receiving the radio-frequency signal from the directional coupler 3, detects the output wave which is the radio-frequency signal, and supplies the output wave to the impedance detector 10.

The reflected wave detector 9, receiving the radio-frequency signal from the directional coupler 4, detects the reflected wave which is the radio-frequency signal, and supplies the reflected wave to the impedance detector 10.

The impedance detector 10 detects the load impedance seen looking into the antenna 7 side from the power amplifier 2 from the output wave detected by the output wave detector 8 and from the reflected wave detected by the reflected wave detector 9.

Since the detecting processing itself of the load impedance seen looking into the antenna 7 side from the power amplifier 2 from the output wave and reflected wave is a publicly known technique, the detailed description thereof will be omitted.

When the impedance detector 10 detects the load impedance seen looking into the antenna 7 side from the power amplifier 2, the control circuit 11 decides on whether the load impedance belongs to the specific region or not.

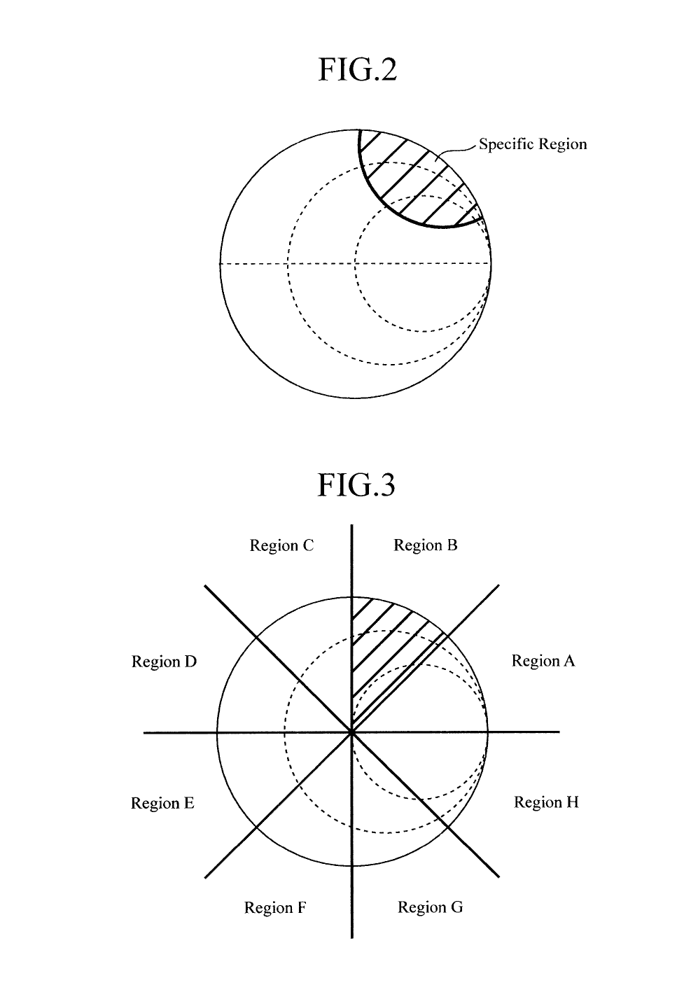

Here, FIG. 2 is a Smith chart showing a specific load impedance (the load impedance detected by the impedance detector 10), in which a shaded area is the specific region. The specific region is appropriately set, considering characteristics of communication equipment and the like in which the front-end amplifier of FIG. 1 is embedded.

The control circuit 11 detects the phase and amplitude of the load impedance detected by the impedance detector 10, and decides that the load impedance belongs to the specific region if the phase is within the phase range of the specific region and the amplitude is within the amplitude range of the specific region.

When the load impedance detected by the impedance detector 10 belongs to the specific region, the control circuit 11 executes at least one of the control of the bias condition of the power amplifier 2 (the control of the idle current or the control of the power supply voltage, for example) and the control of the impedance of the variable-matching circuit 5.

More specifically, if the linearity of the power amplifier 2 deteriorates because the load impedance detected by the impedance detector 10 belongs to the specific region, the control circuit 11 controls the bias circuit 12 so as to recover the linearity by increasing the idle current.

Under the instruction of the control circuit 11, the bias circuit 12 increases the idle current of the power amplifier 2 by adjusting the DC voltage and current supplied to the gate or base of the power amplifier 2.

If the saturation power of the power amplifier 2 reduces because the load impedance detected by the impedance detector 10 belongs to the specific region, the control circuit 11 controls the DC/DC converter 13 so as to recover the saturation power by increasing the power supply voltage.

Under the instruction of the control circuit 11, the DC/DC converter 13 increases the power supply voltage to the power amplifier 2 by controlling the DC voltage and current supplied to the drain or collector of the power amplifier 2.

If the load impedance detected by the impedance detector 10 belongs to the specific region and the load impedance is very wide of the initial state, the control circuit 11 controls the impedance of the variable-matching circuit 5 so as to bring the load impedance closer to the initial state.

In this way, even if the linearity, saturation power and load impedance of the power amplifier 2 vary because of the variation of the impedance of the antenna 7, the control circuit 11 controls the bias circuit 12, DC/DC converter 13 or variable-matching circuit 5 so as to cancel out the variation.

As is manifest in the above, according to the present embodiment 1, it is configured in such a manner that it comprises the power amplifier 2 that amplifies the radio-frequency signal which is the input signal and supplies the radio-frequency signal after the amplification to the antenna 7, and the load impedance detector 10 that detects the load impedance seen looking into the antenna 7 side from the power amplifier 2 from the radio-frequency signal output from the power amplifier 2 and the radio-frequency signal reflected from the antenna 7, and that the control circuit 11 decides on whether the load impedance detected by the impedance detector 10 belongs to the specific region or not, and if the load impedance belongs to the specific region, it controls at least one of the bias condition of the power amplifier 2 and the impedance of the variable-matching circuit 5. Accordingly, the present embodiment 1 offers an advantage of being able to prevent the characteristic alterations of the power amplifier 2 and the destruction of the power amplifier 2 without connecting the isolator between the power amplifier 2 and the antenna 7.

Incidentally, although the present embodiment 1 shows an example in which the specific region is an area with a range where the phase and amplitude are set in advance, the specific region can be an area with a range where at least one of the phase and amplitude is set.

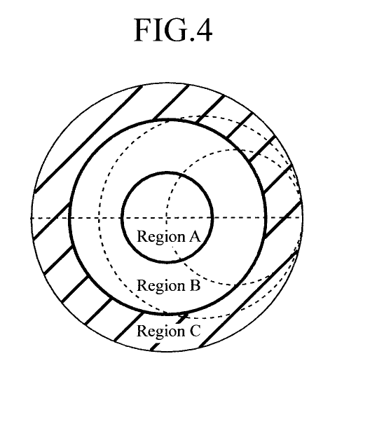

FIG. 3 is a Smith chart showing the load impedance of a specific phase range, in which the shaded region B is the specific region.

In the example of FIG. 3, the control circuit 11 detects the phase of the load impedance detected by the impedance detector 10, and if the phase is located within the region B, it decides that the load impedance belongs to the specific region.

In addition, FIG. 4 is a Smith chart showing a load impedance in a specific amplitude range, in which the shaded region C is the specific region.

In the example of FIG. 4, the control circuit 11 detects the amplitude of the load impedance detected by the impedance detector 10, and if the amplitude is located within the region C, it decides that the load impedance belongs to the specific region.

### Embodiment 2

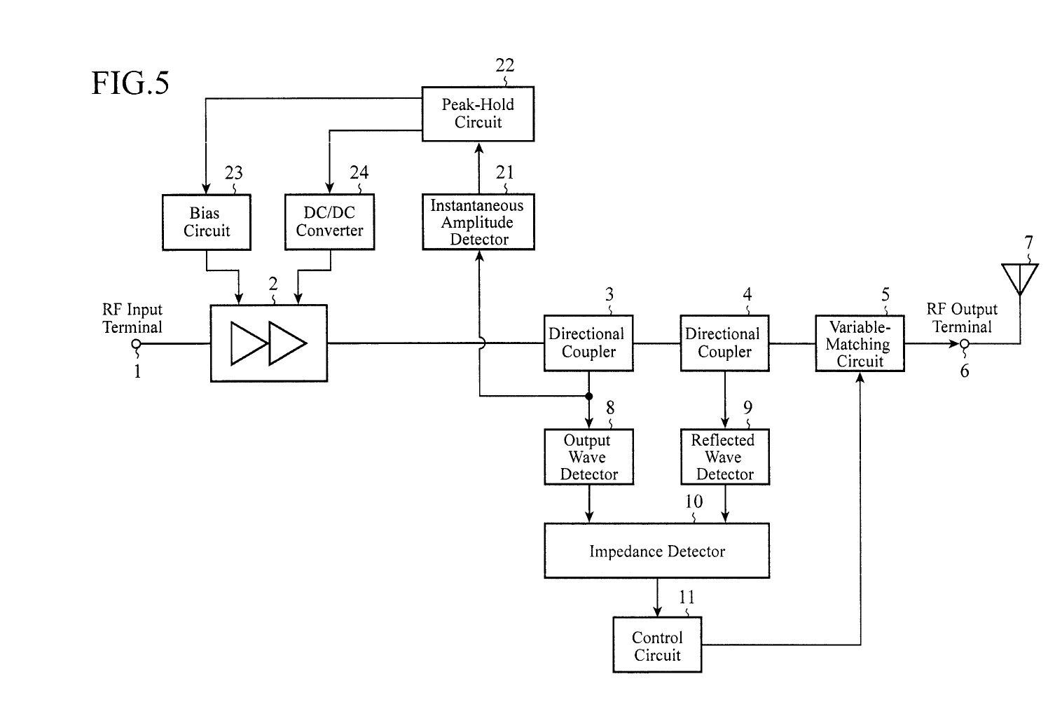

FIG. 5 is a block diagram showing a configuration of a front-end amplifier of an embodiment 2 in accordance with the present invention. In FIG. 5 the same reference numerals as those of FIG. 1 designate the same or like components, and hence their description will be omitted.

An instantaneous amplitude detector 21 is a circuit that detects the instantaneous amplitude of the radio-frequency signal output from the directional coupler 3.

A peak-hold circuit 22 is a circuit that maintains the peak voltage of the instantaneous amplitude detected by the instantaneous amplitude detector 21 for a fixed time period.

More specifically, if the instantaneous amplitude detector 21 detects a peak voltage with instantaneous amplitude higher than the peak voltage maintained by the peak-hold circuit 22, the peak-hold circuit 22 executes update processing of the held peak voltage, which changes the peak voltage being maintained to the peak voltage newly detected, and at the same time executes update processing of the peak voltage being maintained, which reduces gradually with the time elapsed.

A bias circuit 23 is a circuit that reduces the bias voltage supplied to the power amplifier 2 as the peak voltage maintained by the peak-hold circuit 22 increases, and on the contrary increases the bias voltage as the peak voltage reduces. Thus, it adjusts the DC voltage and current to be supplied to the gate or base of the power amplifier 2 in such a manner that they are inversely proportional to the peak voltage maintained by the peak-hold circuit 22.

A DC/DC converter 24 is a circuit that reduces the bias voltage supplied to the power amplifier 2 as the peak voltage maintained by the peak-hold circuit 22 increases, and on the contrary increases the bias voltage as the peak voltage reduces. Thus, it adjusts the DC voltage and current to be supplied to the drain or collector of the power amplifier 2 in such a manner that they are inversely proportional to the peak voltage maintained by the peak-hold circuit 22.

Incidentally, the bias circuit 23 and the DC/DC converter 24 constitute a control unit.

Next, the operation will be described.

The radio-frequency signal input to the RF input terminal 1 is supplied to the power amplifier 2 and the power amplifier 2 amplifies the radio-frequency signal which is the input signal.

The radio-frequency signal amplified by the power amplifier 2 is supplied to the antenna 7 connected to the RE' output terminal 6, and is emitted into space from the antenna 7.

On this occasion, the impedance of the antenna 7 is not always constant, but varies as a user approaches or touches the antenna 7, for example.

To prevent the characteristic alterations or destruction of the power amplifier 2 even if the impedance of the antenna 7 varies, the present embodiment 2 executes the following processing.

When the output wave detector 8 detects the output wave and the reflected wave detector 9 detects the reflected wave, the impedance detector 10 detects the load impedance seen looking into the antenna 7 side from the power amplifier 2 from the output wave and reflected wave in the same manner as in the foregoing embodiment 1.

When the impedance detector 10 detects the load impedance seen looking into the antenna 7 side from the power amplifier 2, the control circuit 11 decides on whether the load impedance belongs to the specific region or not in the same manner as in the foregoing embodiment 1.

If the load impedance detected by the impedance detector 10 belongs to the specific region, the control circuit 11 controls the impedance of the variable-matching circuit 5.

More specifically, if the load impedance detected by the impedance detector 10 belongs to the specific region and the load impedance is very wide of the initial state, the control circuit 11 controls the impedance of the variable-matching circuit 5 so as to bring the load impedance closer to the initial state.

In the present embodiment 2, the control circuit 11 does not carries out the control of the bias condition of the power amplifier 2 (control of the idle current or control of the power supply voltage, for example).

When the directional coupler 3 extracts a part of the radio-frequency signal after the amplification and outputs the radio-frequency signal, the instantaneous amplitude detector 21 detects the instantaneous amplitude of the radio-frequency signal.

The peak-hold circuit 22 retains the peak voltage of the instantaneous amplitude detected by the instantaneous amplitude detector 21 for a fixed time period.

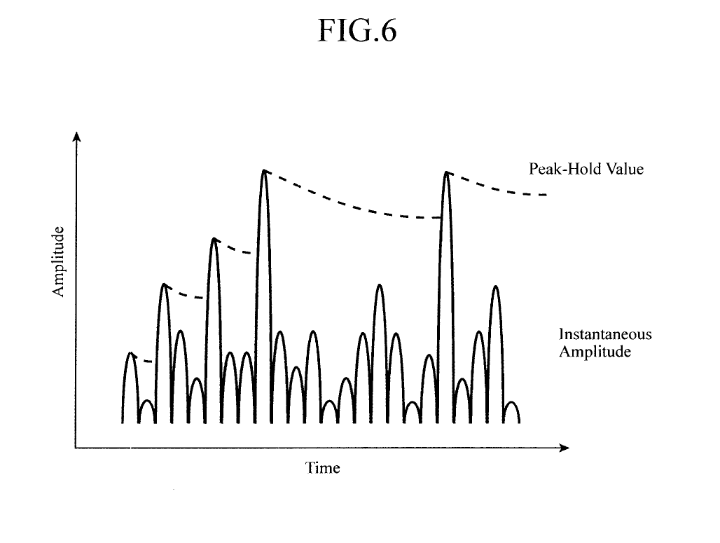

Here, FIG. 6 is a diagram illustrating the instantaneous amplitude detected by the instantaneous amplitude detector 21 and the peak voltage maintained by the peak-hold circuit 22.

As is manifest in FIG. 6, if the instantaneous amplitude detector 21 newly detects a peak voltage of the instantaneous amplitude higher than the peak voltage being maintained, the peak-hold circuit 22 executes the update processing of the held peak voltage, which changes the peak voltage being maintained to the peak voltage newly detected.

In addition, the peak-hold circuit 22 carries out the update processing of the peak voltage being maintained, which gradually reduces its peak voltage with the time elapsed.

The bias circuit 23 reduces the bias voltage supplied to the power amplifier 2 as the peak voltage maintained by the peak-hold circuit 22 increases, and on the contrary increases the bias voltage as the peak voltage reduces. Thus, it adjusts the DC voltage and current to be supplied to the gate or base of the power amplifier 2 in such a manner that they are inversely proportional to the peak voltage maintained by the peak-hold circuit 22.

The DC/DC converter 24 reduces the bias voltage supplied to the power amplifier 2 as the peak voltage maintained by the peak-hold circuit 22 increases, and on the contrary increases the bias voltage as the peak voltage reduces. Thus, it adjusts the DC voltage and current to be supplied to the drain or collector of the power amplifier 2 in such a manner that they are inversely proportional to the peak voltage maintained by the peak-hold circuit 22.

Thus altering the impedance of the antenna 7 can, even if the linearity, saturation power and load impedance of the power amplifier 2 vary, control the bias circuit 23, DC/DC converter 24 or variable-matching circuit 5 in such a manner as to cancel out their variations.

Here, although an example is shown in which both the bias circuit 23 and DC/DC converter 24 control the bias voltage to be supplied to the power amplifier 2, a configuration is also possible in which at least one of the bias circuit 23 and DC/DC converter 24 controls the bias voltage to be supplied to the power amplifier 2.

In addition, although the configuration is shown which adjusts the DC voltage and current to be supplied to the gate or base of the power amplifier 2 in such a manner that they are inversely proportional to the peak voltage maintained by the peak-hold circuit 22 so as to reduce the bias voltage supplied to the power amplifier 2 as the peak voltage maintained by the peak-hold circuit 22 increases, and on the contrary to increase the bias voltage as the peak voltage reduces, the configuration is not limited to that. For example, any configuration is possible which does not necessarily adjust the DC voltage and current in such a manner that they are inversely proportional to the peak voltage maintained as long as the bias voltage supplied to the power amplifier 2 is reduced as the peak voltage increases, and on the contrary the bias voltage is increased as the peak voltage reduces.

As is manifest in the above, according to the present embodiment 2, it is configured in such a manner that it comprises the power amplifier 2 that amplifies the radio-frequency signal which is the input signal and supplies the radio-frequency signal after the amplification to the antenna 7, the instantaneous amplitude detector 21 that detects the instantaneous amplitude of the radio-frequency signal output from the power amplifier 2, and the peak-hold circuit 22 that maintains the peak voltage of the instantaneous amplitude detected by the instantaneous amplitude detector 21 for a fixed time period, and that at least one of the bias circuit 23 and DC/DC converter 24 supplies the power amplifier 2 with the bias voltage that reduces as the peak voltage maintained by the peak-hold circuit 22 increases, and on the contrary with the bias voltage that increases as the peak voltage reduces. Accordingly, it offers an advantage of being able to prevent the characteristic alterations of the power amplifier 2 and the destruction of the power amplifier 2 without connecting the isolator between the power amplifier 2 and the antenna 7.

### Embodiment 3

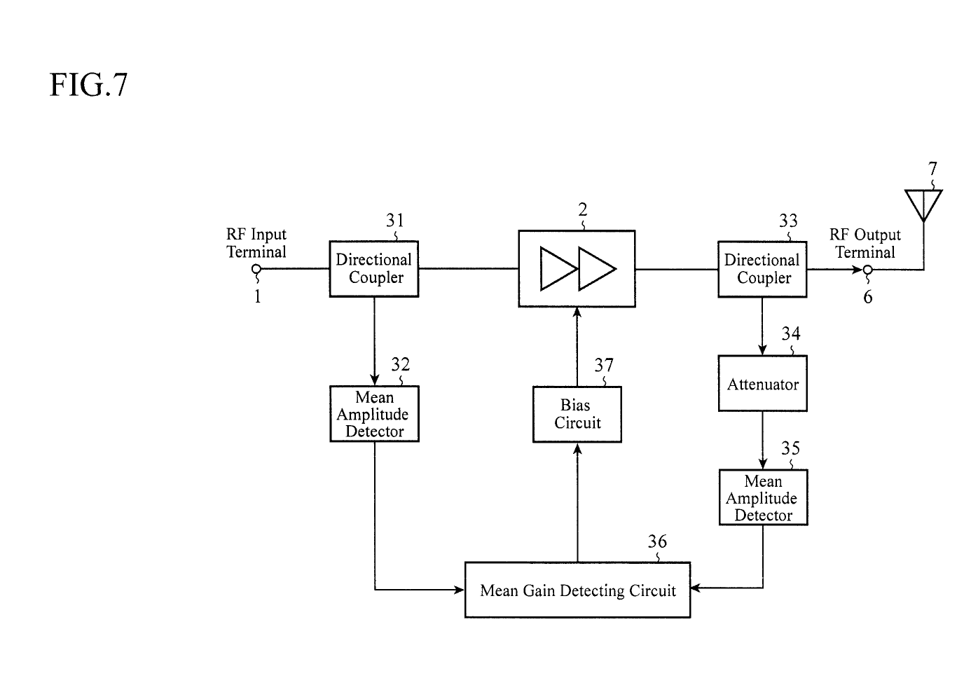

FIG. 7 is a block diagram showing a configuration of a front-end amplifier of an embodiment 3 in accordance with the present invention. In FIG. 7, the same reference numerals as those of FIG. 1 designate the same or like components, and hence their description will be omitted.

A directional coupler 31 is a device that extracts a part of the radio-frequency signal input via the RF input terminal 1, and supplies the part of the radio-frequency signal to a mean amplitude detector 32.

The mean amplitude detector 32 is a device that detects the mean amplitude of the radio-frequency signal output from the directional coupler 31.

A directional coupler 33 is a device that extracts a part of the radio-frequency signal output from the power amplifier 2, and supplies the part of the radio-frequency signal to an attenuator 34.

The attenuator 34 is a device that attenuates the signal level of the radio-frequency signal supplied from the directional coupler 33.

The mean amplitude detector 35 is a device that detects the mean amplitude of the radio-frequency signal, the signal level of which is attenuated by the attenuator 34.

A mean gain detecting circuit 36 is a circuit that detects the mean gain of the power amplifier 2 from the mean amplitude at the input side of the power amplifier 2 detected by the mean amplitude detector 32 and from the mean amplitude at the output side of the power amplifier 2 detected by the mean amplitude detector 35.

Incidentally, the directional coupler 31, mean amplitude detector 32, directional coupler 33, attenuator 34, mean amplitude detector 35 and mean gain detecting circuit 36 constitute a gain detecting unit.

A bias circuit 37 is a circuit that controls the idle current of the power amplifier 2 in such a manner that the mean gain detected by the mean gain detecting circuit 36 becomes constant by adjusting the DC voltage and current to be supplied to the gate or base of the power amplifier 2. Incidentally, the bias circuit 37 constitutes a control unit.

Next, the operation will be described.

The radio-frequency signal input via the RF input terminal 1 is supplied to the power amplifier 2, and the power amplifier 2 amplifies the radio-frequency signal which is the input signal.

The radio-frequency signal amplified by the power amplifier 2 is supplied to the antenna 7 connected to the RF output terminal 6, and the antenna 7 emits the radio-frequency signal after the amplification into the space.

On this occasion, the impedance of the antenna 7 is not always constant, but varies as a user approaches or contacts the antenna 7.

To prevent the characteristic alterations or destruction of the power amplifier 2 even if the impedance of the antenna 7 varies, the present embodiment 3 executes the following processing.

The directional coupler 31 extracts a part of the radio-frequency signal fed from the RF input terminal 1, and supplies the part of the radio-frequency signal to the mean amplitude detector 32.

The mean amplitude detector 32, receiving the radio-frequency signal from the directional coupler 31, detects the mean amplitude of the radio-frequency signal, and supplies the mean amplitude to the mean gain detecting circuit 36.

The directional coupler 33, receiving the radio-frequency signal after the amplification by the power amplifier 2, extracts a part of the radio-frequency signal, and supplies the part of the radio-frequency signal to the attenuator 34.

The attenuator 34, receiving the radio-frequency signal from the directional coupler 33, attenuates the signal level of the radio-frequency signal, and supplies the radio-frequency signal after the level attenuation to the mean amplitude detector 35.

For example, the attenuator 34 is a component that attenuates the signal level of the radio-frequency signal at the attenuation factor corresponding to the amplification factor of the power amplifier 2. If the characteristics of the power amplifier 2 are consistent, the mean amplitude of the radio-frequency signal after the level attenuation by the attenuator 34 will be equal to the mean amplitude of the radio-frequency signal before the amplification by the power amplifier 2.

The mean amplitude detector 35, receiving the radio-frequency signal after the level attenuation from the attenuator 34, detects the mean amplitude of the radio-frequency signal and supplies the mean amplitude to the mean gain detecting circuit 36.

The mean gain detecting circuit 36, receiving the mean amplitude at the input side of the power amplifier 2 from the mean amplitude detector 32 and the mean amplitude at the output side of the power amplifier 2 from the mean amplitude detector 35, detects the mean gain of the power amplifier 2 from the mean amplitude at the input side and the mean amplitude at the output side.

mean gain=mean amplitude at output side/mean amplitude at input side

When the mean gain detecting circuit 36 detects the mean gain of the power amplifier 2, the bias circuit 37 adjusts the DC voltage and current to be supplied to the gate or base of the power amplifier 2 in such a manner that the mean gain becomes constant, thereby controlling the idle current of the power amplifier 2.

More specifically, if the mean gain of the power amplifier 2 detected by the mean gain detecting circuit 36 is higher than a reference gain (the gain of the power amplifier 2 when the characteristics of the power amplifier 2 are consistent, for example), the bias circuit 37 adjusts the DC voltage and current to be supplied to the gate or base of the power amplifier 2 in such a manner as to reduce them, whereas if the mean gain of the power amplifier 2 detected by the mean gain detecting circuit 36 is lower than the reference gain, it adjusts the DC voltage and current t o be supplied to the gate or base of the power amplifier 2 in such a manner as to increase them.

This causes the bias circuit 37 to operate so as to cancel out the variation in the gain of the power amplifier 2, even if the gain is altered owing to the variation of the impedance of the antenna 7.

As is manifest in the above, according to the present embodiment 3, it is configured in such a manner that it comprises the power amplifier 2 that amplifies the radio-frequency signal which is the input signal and supplies the radio-frequency signal after the amplification to the antenna 7, and the mean gain detecting circuit 36 that detects the mean gain of the power amplifier 2 from the input signal and the radio-frequency signal output from the power amplifier 2, and that the bias circuit 37 controls the bias voltage to be supplied to the power amplifier 2 in such a manner that the mean gain detected by the mean gain detecting circuit 36 becomes constant. Accordingly, it offers an advantage of being able to prevent the characteristic alterations of the power amplifier 2 and the destruction of the power amplifier 2 without connecting the isolator between the power amplifier 2 and the antenna 7.

### Embodiment 4

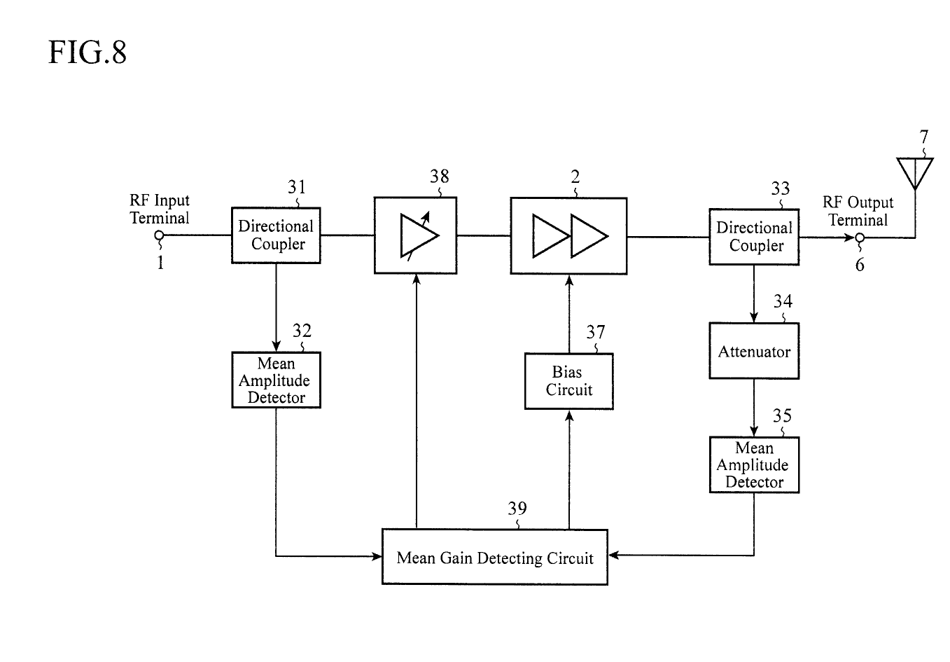

FIG. 8 is a block diagram showing a configuration of a front-end amplifier of an embodiment 4 in accordance with the present invention. In FIG. 8, the same reference numerals as those of FIG. 7 designate the same or like components, and hence their description will be omitted.

A variable-gain amplifier 38 is a gain adjusting amplifier and is connected before the power amplifier 2.

A mean gain detecting circuit 39 is a circuit that detects the total mean gain of the power amplifier 2 and variable-gain amplifier 38 from the mean amplitude at the input side of the power amplifier 2 detected by the mean amplitude detector 32 and from the mean amplitude at the output side of the power amplifier 2 detected by the mean amplitude detector 35, and controls the bias circuit 37 or the variable-gain amplifier 38 in such a manner that the total mean gain becomes constant. Incidentally, the mean gain detecting circuit 39 constitutes a gain detecting unit and a control unit.

Next, the operation will be described.

The radio-frequency signal input via the RF input terminal 1 is supplied to the power amplifier 2, and the power amplifier 2 amplifies the radio-frequency signal which is the input signal.

The radio-frequency signal amplified by the power amplifier 2 is supplied to the antenna 7 connected to the RF output terminal 6, and the antenna 7 emits the radio-frequency signal after the amplification into the space.

On this occasion, the impedance of the antenna 7 is not always constant, but varies as a user approaches or contacts the antenna 7.

To prevent the characteristic alterations or destruction of the power amplifier 2 even if the impedance of the antenna 7 varies, the present embodiment 4 executes the following processing.

The directional coupler 31 extracts a part of the radio-frequency signal input via the RF input terminal 1, and supplies the part of the radio-frequency signal to the mean amplitude detector 32 as in the foregoing embodiment 3.

The mean amplitude detector 32, receiving the radio-frequency signal from the directional coupler 31, detects the mean amplitude of the radio-frequency signal, and supplies the mean amplitude to the mean gain detecting circuit 39 as in the foregoing embodiment 3.

The directional coupler 33 extracts, when the power amplifier 2 outputs the radio-frequency signal after the amplification, a part of the radio-frequency signal as in the foregoing embodiment 3, and supplies the part of the radio-frequency signal to the attenuator 34.

The attenuator 34, receiving the radio-frequency signal from the directional coupler 33, attenuates the signal level of the radio-frequency signal as in the foregoing embodiment 3, and supplies the radio-frequency signal after the level attenuation to the mean amplitude detector 35.

The mean amplitude detector 35, receiving the radio-frequency signal after the level attenuation from the attenuator 34, detects the mean amplitude of the radio-frequency signal as in the foregoing embodiment 3, and supplies the mean amplitude to the mean gain detecting circuit 39.

The mean gain detecting circuit 39, receiving the mean amplitude at the input side of the power amplifier 2 from the mean amplitude detector 32 and receiving the mean amplitude at the output side of the power amplifier 2 from the mean amplitude detector 35, detects the total mean gain of the power amplifier 2 and variable-gain amplifier 38 from the mean amplitude at the input side and the mean amplitude at the output side.

total mean gain=mean amplitude at output side/mean amplitude at input side

Detecting the total mean gain of the power amplifier 2 and variable-gain amplifier 38, the mean gain detecting circuit 39 controls the bias circuit 37 or variable-gain amplifier 38 in such a manner that the total mean gain becomes constant.

When the mean gain detecting circuit 39 controls the bias circuit 37, the bias circuit 37 controls the idle current of the power amplifier 2 by adjusting the DC voltage and current to be supplied to the gate or base of the power amplifier 2 in such a manner that the total mean gain becomes constant.

More specifically, if the total mean gain detected by the mean gain detecting circuit 39 is higher than a reference gain (the total gain of the power amplifier 2 and the variable-gain amplifier 38 when the characteristics of the power amplifier 2 are consistent, for example), the bias circuit 37 adjusts the DC voltage and current to be supplied to the gate or base of the power amplifier 2 in such a manner as to reduce them, whereas if the total mean gain detected by the mean gain detecting circuit 39 is lower than the reference gain, it adjusts the DC voltage and current to be supplied to the gate or base of the power amplifier 2 in such a manner as to increase them.

When the mean gain detecting circuit 39 controls the variable-gain amplifier 38, it adjusts the gain of the variable-gain amplifier 38 in such a manner that the total mean gain becomes constant.

More specifically, the mean gain detecting circuit 39 controls in such a manner that if the total mean gain is higher than the reference gain, it reduces the gain of the variable-gain amplifier 38, and that if the total mean gain is lower than the reference gain, it increases the gain of the variable-gain amplifier 38.

This causes the bias circuit 37 or variable-gain amplifier 38 to operate so as to cancel out the variation in the gain of the power amplifier 2, even if the gain is altered owing to the variation of the impedance of the antenna 7.

As is manifest in the above, according to the present embodiment 4, it is configured in such a manner that it comprises the power amplifier 2 that amplifies the radio-frequency signal which is the input signal and supplies the radio-frequency signal after the amplification to the antenna 7, the variable-gain amplifier 38 connected before the power amplifier, and the mean gain detecting circuit 39 that detects the total mean gain of the power amplifier 2 and variable-gain amplifier 38 from the input signal and the radio-frequency signal output from the power amplifier 2, and that the mean gain detecting circuit 39 controls the gain of the variable-gain amplifier 38 in such a manner that the total mean gain becomes constant. Accordingly, it offers an advantage of being able to prevent the characteristic alterations of the power amplifier 2 and the destruction of the power amplifier 2 without connecting the isolator between the power amplifier 2 and the antenna 7.

### Embodiment 5

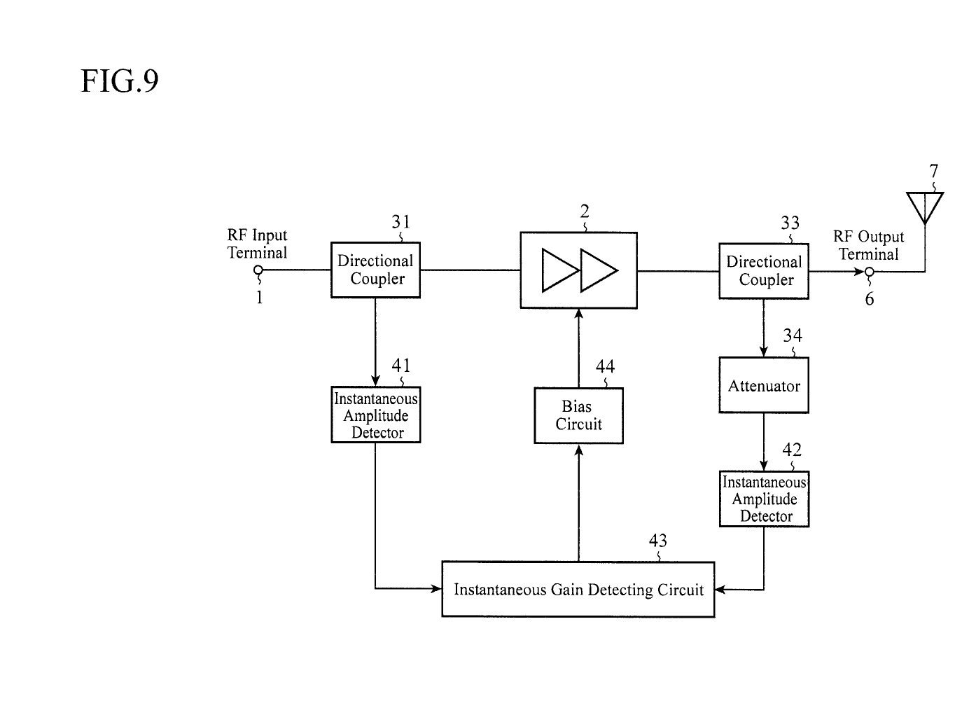

FIG. 9 is a block diagram showing a configuration of a front-end amplifier of an embodiment 5 in accordance with the present invention. In FIG. 9, the same reference numerals as those of FIG. 7 designate the same or like components, and hence their description will be omitted.

An instantaneous amplitude detector 41 is a device that detects the instantaneous amplitude of the radio-frequency signal output from the directional coupler 31.

An instantaneous amplitude detector 42 is a device that detects the instantaneous amplitude of the radio-frequency signal, the signal level of which is attenuated by the attenuator 34.

An instantaneous gain detecting circuit 43 is a circuit that detects the instantaneous gain of the power amplifier 2 from the instantaneous amplitude at the input side of the power amplifier 2 detected by the instantaneous amplitude detector 41 and the instantaneous amplitude at the output side of the power amplifier 2 detected by the instantaneous amplitude detector 42.

Incidentally, the directional couplers 31 and 33, the attenuator 34, the instantaneous amplitude detectors 41 and 42 and the instantaneous gain detecting circuit 43 constitute a gain detecting unit.

A bias circuit 44 is a circuit that controls the idle current of the power amplifier 2 by adjusting the DC voltage and current to be supplied to the gate or base of the power amplifier 2 in such a manner that the instantaneous gain detected by the instantaneous gain detecting circuit 43 becomes constant. Incidentally, the bias circuit 44 constitutes a control unit.

Next, the operation will be described.

The radio-frequency signal input via the RF input terminal 1 is supplied to the power amplifier 2, and the power amplifier 2 amplifies the radio-frequency signal which is the input signal.

The radio-frequency signal amplified by the power amplifier 2 is supplied to the antenna 7 connected to the RE output terminal 6, and the radio-frequency signal after the amplification is emitted from the antenna 7 into the space.

On this occasion, the impedance of the antenna 7 is not always constant, but varies as a user approaches or contacts the antenna 7.

To prevent the characteristic alterations or destruction of the power amplifier 2 even if the impedance of the antenna 7 varies, the present embodiment 5 executes the following processing.

The directional coupler 31 extracts a part of the radio-frequency signal fed from the RF input terminal 1 as in the foregoing embodiment 3, and supplies the part of the radio-frequency signal to the instantaneous amplitude detector 41.

The instantaneous amplitude detector 41, receiving the radio-frequency signal from the directional coupler 31, detects the instantaneous amplitude of the radio-frequency signal, and supplies the instantaneous amplitude to the instantaneous gain detecting circuit 43.

The directional coupler 33 extracts, when the power amplifier 2 outputs the radio-frequency signal after the amplification, a part of the radio-frequency signal as in the foregoing embodiment 3, and supplies the part of the radio-frequency signal to the attenuator 34.

The attenuator 34, receiving the radio-frequency signal from the directional coupler 33, attenuates the signal level of the radio-frequency signal as in the foregoing embodiment 3, and supplies the radio-frequency signal after the level attenuation to the instantaneous amplitude detector 42.

The instantaneous amplitude detector 42, receiving the radio-frequency signal after the level attenuation from the attenuator 34, detects the instantaneous amplitude of the radio-frequency signal, and supplies the instantaneous amplitude to the instantaneous gain detecting circuit 43.

The instantaneous gain detecting circuit 43, receiving the instantaneous amplitude at the input side of the power amplifier 2 from the Instantaneous amplitude detector 41 and receiving the instantaneous amplitude at the output side of the power amplifier 2 from the instantaneous amplitude detector 42, detects the instantaneous gain of the power amplifier 2 from the input side instantaneous amplitude and from the output side instantaneous amplitude.

instantaneous gain=output side instantaneous amplitude/input side instantaneous amplitude

The bias circuit 44 controls, when the instantaneous gain detecting circuit 43 detects the instantaneous gain of the power amplifier 2, the idle current of the power amplifier 2 in such a manner that the instantaneous gain becomes constant by adjusting the DC voltage and current to be supplied to the gate or base of the power amplifier 2.

More specifically, if the instantaneous gain of the power amplifier 2 detected by the instantaneous gain detecting circuit 43 is higher than a reference gain (the gain of the power amplifier 2 when the characteristics of the power amplifier 2 are consistent, for example), the bias circuit 44 adjusts the DC voltage and current to be supplied to the gate or base of the power amplifier 2 in such a manner as to reduce them, whereas if the instantaneous gain of the power amplifier 2 detected by the instantaneous gain detecting circuit 43 is lower than the reference gain, it adjusts the DC voltage and current to be supplied to the gate or base of the power amplifier 2 in such a manner as to increase them.

This causes the bias circuit 44 to operate so as to cancel out distortion, even if the distortion due to nonlinear characteristics (AM-AM characteristics) of the gain of the power amplifier 2 occurs owing to the variation of the impedance of the antenna 7.

As is manifest in the above, according to the present embodiment 5, it is configured in such a manner that it comprises the power amplifier 2 that amplifies the radio-frequency signal which is the input signal and supplies the radio-frequency signal after the amplification to the antenna 7, and the instantaneous gain detecting circuit 43 that detects the instantaneous gain of the power amplifier 2 from the input signal and the radio-frequency signal output from the power amplifier 2, and that the bias circuit 44 controls the bias voltage to be supplied to the power amplifier 2 in such a manner that the instantaneous gain detected by the instantaneous gain detecting circuit 43 becomes constant. Accordingly, it offers an advantage of being able to prevent the characteristic alterations of the power amplifier 2 and the destruction of the power amplifier 2 without connecting the isolator between the power amplifier 2 and the antenna 7.

### Embodiment 6

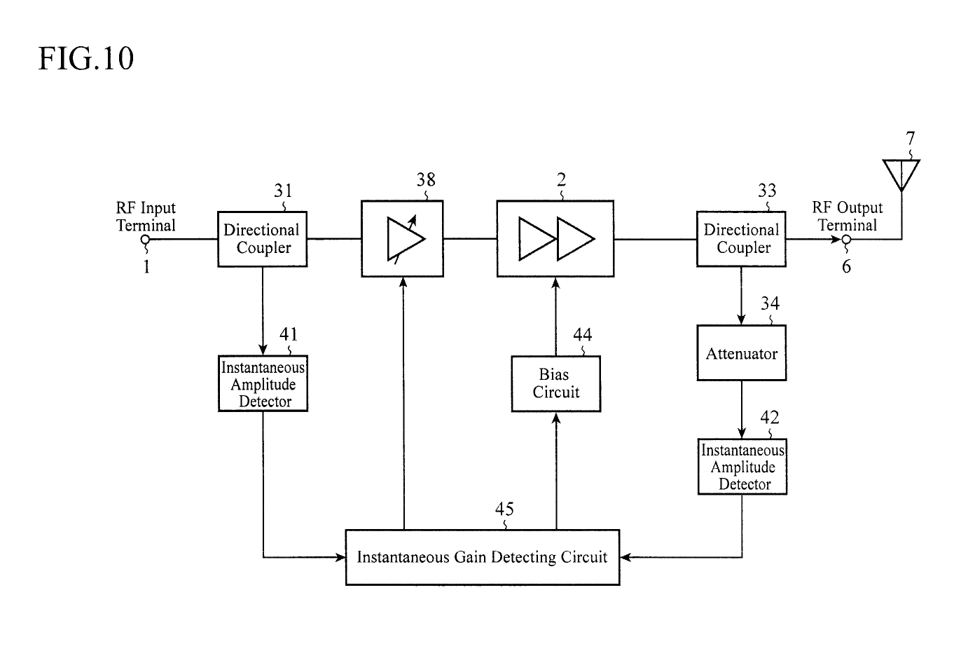

FIG. 10 is a block diagram showing a configuration of a front-end amplifier of an embodiment 6 in accordance with the present invention. In FIG. 10, the same reference numerals as those of FIG. 8 and FIG. 9 designate the same or like components, and hence their description will be omitted.

An instantaneous gain detecting circuit 45 is a circuit that detects the total instantaneous gain of the power amplifier 2 and variable-gain amplifier 38 from the instantaneous amplitude at the input side of the power amplifier 2 detected by the instantaneous amplitude detector 41 and from the instantaneous amplitude at the output side of the power amplifier 2 detected by the instantaneous amplitude detector 42, and controls the bias circuit 44 or the variable-gain amplifier 38 in such a manner that the total instantaneous gain becomes constant. Incidentally, the instantaneous gain detecting circuit 45 constitutes a gain detecting unit and a control unit.

Next, The operation will be described.

The radio-frequency signal input via the RF input terminal 1 is supplied to the power amplifier 2, and the power amplifier 2 amplifies the radio-frequency signal which is the input signal.

The radio-frequency signal amplified by the power amplifier 2 is supplied to the antenna 7 connected to the RF output terminal 6, and the antenna 7 emits the radio-frequency signal after the amplification into the space.

On this occasion, the impedance of the antenna 7 is not always constant, but varies as a user approaches or contacts the antenna 7.

To prevent the characteristic alterations or destruction of the power amplifier 2 even if the impedance of the antenna 7 varies, the present embodiment 6 executes the following processing.

The directional coupler 31 extracts a part of the radio-frequency signal input via the RF input terminal 1 as in the foregoing embodiment 5, and supplies the part of the radio-frequency signal to the instantaneous amplitude detector 41.

The instantaneous amplitude detector 41, receiving the radio-frequency signal from the directional coupler 31, detects the instantaneous amplitude of the radio-frequency signal as in the foregoing embodiment 5, and supplies the instantaneous amplitude to the instantaneous gain detecting circuit 45.

The directional coupler 33 extracts, when the power amplifier 2 outputs the radio-frequency signal after the amplification, a part of the radio-frequency signal as in the foregoing embodiment 5, and supplies the part of the radio-frequency signal to the attenuator 34.

The attenuator 34, receiving the radio-frequency signal from the directional coupler 33, attenuates the signal level of the radio-frequency signal as in the foregoing embodiment 5, and supplies the radio-frequency signal after the level attenuation to the instantaneous amplitude detector 42.

The instantaneous amplitude detector 42, receiving the radio-frequency signal after the level attenuation from the attenuator 34, detects the instantaneous amplitude of the radio-frequency signal as in the foregoing embodiment 5, and supplies the instantaneous amplitude to the instantaneous gain detecting circuit 45.

The instantaneous gain detecting circuit 45, receiving the instantaneous amplitude at the input side of the power amplifier 2 from the instantaneous amplitude detector 41 and receiving the instantaneous amplitude at the output side of the power amplifier 2 from the instantaneous amplitude detector 42, detects the total instantaneous gain of the power amplifier 2 and variable-gain amplifier 38 from the input side instantaneous amplitude and the output side instantaneous amplitude.

total instantaneous gain=output side instantaneous amplitude/input side instantaneous amplitude

The instantaneous gain detecting circuit 45, when detecting the total instantaneous gain of the power amplifier 2 and variable-gain amplifier 38, controls the bias circuit 44 or variable-gain amplifier 38 in such a manner that the total instantaneous gain becomes constant.

When the instantaneous gain detecting circuit 45 controls the bias circuit 44, the bias circuit 44 controls the idle current of the power amplifier 2 by adjusting the DC voltage and current to be supplied to the gate or base of the power amplifier 2 in such a manner that the total instantaneous gain becomes constant.

More specifically, if the total instantaneous gain detected by the instantaneous gain detecting circuit 45 is higher than a reference gain (the total gain of the power amplifier 2 and variable-gain amplifier 38 when the characteristics of the power amplifier 2 are consistent, for example), the bias circuit 44 adjusts the DC voltage and current to be supplied to the gate or base of the power amplifier 2 in such a manner as to reduce them, whereas if the total instantaneous gain detected by the instantaneous gain detecting circuit 45 is lower than the reference gain, it adjusts the DC voltage and current to be supplied to the gate or base of the power amplifier 2 in such a manner as to increase them.

When the instantaneous gain detecting circuit 45 controls the variable-gain amplifier 38, it adjusts the gain of the variable-gain amplifier 38 in such a manner that the total instantaneous gain becomes constant.

More specifically, the instantaneous gain detecting circuit 45 controls in such a manner that if the total instantaneous gain is higher than the reference gain, it reduces the gain of the variable-gain amplifier 38, and that if the total instantaneous gain is lower than the reference gain, it increases the gain of the variable-gain amplifier 38.

This causes the bias circuit 44 or variable-gain amplifier 38 to operate so as to cancel out distortion, even if the distortion due to nonlinear characteristics (AM-AM characteristics) of the gain of the power amplifier 2 occurs owing to the variation of the impedance of the antenna 7.

As is manifest in the above, according to the present embodiment 6, it is configured in such a manner that it comprises the power amplifier 2 that amplifies the radio-frequency signal which is the input signal and supplies the radio-frequency signal after the amplification to the antenna 7, the variable-gain amplifier 38 connected before the power amplifier, and the instantaneous gain detecting circuit 45 that detects the total instantaneous gain of the power amplifier 2 and the variable-gain amplifier 38 from the input signal and the radio-frequency signal output from the power amplifier 2, and that the instantaneous gain detecting circuit 45 controls the gain of the variable-gain amplifier 38 in such a manner that the total instantaneous gain becomes constant. Accordingly, it offers an advantage of being able to prevent the characteristic alterations of the power amplifier 2 and the destruction of the power amplifier 2 without connecting the isolator between the power amplifier 2 and the antenna 7.

### Embodiment 7

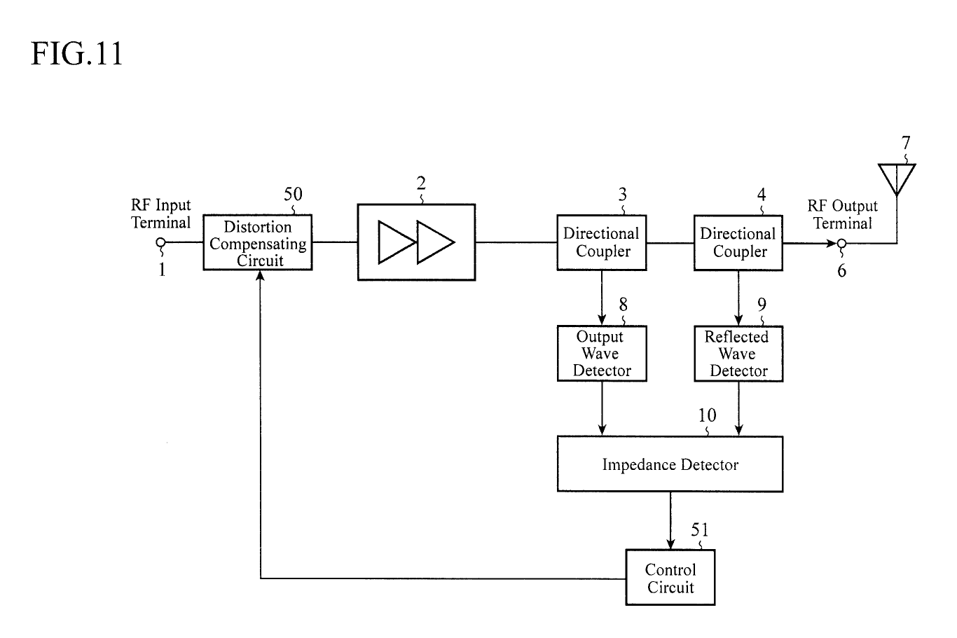

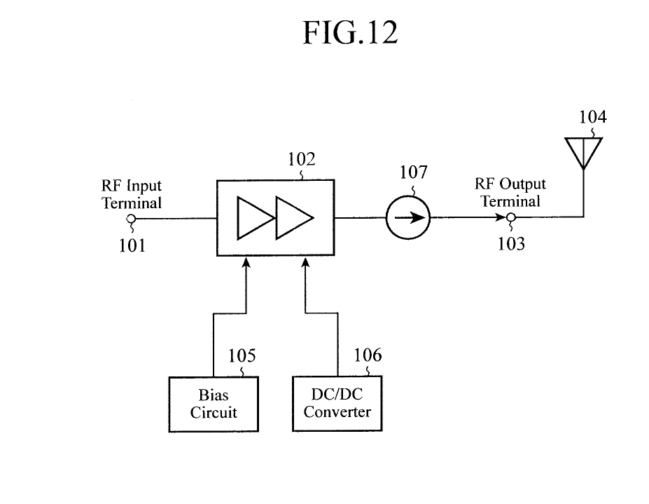

FIG. 11 is a block diagram showing a configuration of a front-end amplifier of an embodiment 7 in accordance with the present invention. In FIG. 11, the same reference numerals as those of FIG. 1 designate the same or like components, and hence their description will be omitted.

A distortion compensating circuit 50, which is an analog device (analog circuit) comprising a diode or transistor, for example, is connected to the input side of the power amplifier 2.

The distortion compensating circuit 50 is a circuit that compensates for the nonlinear distortion occurring in the power amplifier 2 by providing nonlinear characteristics to the radio-frequency signal input via the RF input terminal 1.

A control circuit 51 is a circuit that decides on whether the load impedance detected by the impedance detector 10 belongs to a specific region (a region in which the phase and amplitude are set in advance) or not, and that carries out, if the load impedance belongs to the specific region, the control of a bias condition of the distortion compensating circuit 50 (bias voltage of the diode or transistor constituting the distortion compensating circuit 50, for example). Incidentally, the control circuit 51 constitutes a control unit.

Next, the operation will be described.

The radio-frequency signal input to the RF input terminal 1 is supplied to the power amplifier 2 via the distortion compensating circuit 50, and the power amplifier 2 amplifies the radio-frequency signal which is the input signal.

The radio-frequency signal amplified by the power amplifier 2 is supplied to the antenna 7 connected to the RE output terminal 6, and is emitted into the space from the antenna 7.

On this occasion, the impedance of the antenna 7 is not always constant, but varies as a user approaches or touches the antenna 7, for example.

Although it is ideal that the whole radio-frequency signal supplied from the RF output terminal 6 to the antenna 7 is emitted into the space, a part of the radio-frequency signal is reflected from the antenna 7 owing to the variation of the impedance of the antenna 7. The amount of the radio-frequency signal reflected relates to the amount of variation in the impedance.

To prevent the characteristic alterations or destruction of the power amplifier 2 even if the impedance of the antenna 7 varies, the present embodiment 7 executes the following processing.

The control circuit 51 controls the bias condition of the distortion compensating circuit 50 when the load impedance detected by the impedance detector 10 belongs to the specific region.

More specifically, if the linearity of the power amplifier 2 deteriorates because the load impedance detected by the impedance detector 10 belongs to the specific region, the control circuit 51 controls the bias condition of the distortion compensating circuit 50 in such a manner as to compensate for the deterioration in the linearity of the power amplifier 2, thereby controlling the nonlinear characteristics.

For example, if the power amplifier 2 has such nonlinear characteristics that will reduce its gain against an increase in its input power because the load impedance belongs to the specific region, the bias condition of the distortion compensating circuit 50 undergoes control in such a manner that the distortion compensating circuit 50 has reverse characteristics, that is, has nonlinear characteristics that will increase the gain with the increase in the input power.

As is manifest in the above, according to the present embodiment 7, it is configured in such a manner that it comprises the power amplifier 2 that amplifies the radio-frequency signal which is the input signal and supplies the radio-frequency signal after the amplification to the antenna 7, and the load impedance detector 10 that detects the load impedance seen looking into the antenna 7 side from the power amplifier 2 from the radio-frequency signal output from the power amplifier 2 and the radio-frequency signal reflected from the antenna 7, and that the control circuit 51 decides on whether the load impedance detected by the impedance detector 10 belongs to the specific region or not, and if the load impedance belongs to the specific region, it controls the bias condition of the distortion compensating circuit 50. Accordingly, the present embodiment 7 offers an advantage of being able to prevent the characteristic alterations of the power amplifier 2 and the destruction of the power amplifier 2 without connecting the isolator between the power amplifier 2 and the antenna 7.

Incidentally, although the present embodiment 7 shows an example in which the specific region is an area with a range where the phase and amplitude are set in advance, the specific region can be an area with a range where at least one of the phase and amplitude is set. As for the other operation and advantages, since they are the same as those of the foregoing embodiment 1, their description will be omitted.

Although the present embodiment 7 shows an example in which the distortion compensating circuit 50 is an analog device that comprises a diode or transistor, the distortion compensating circuit 50 can be a circuit as shown below.

More specifically, it can be a polar-loop feedback distortion compensating circuit that detects the amplitude component and phase component of the radio-frequency signal input via the RF Input terminal 1 (input signal), and detects the amplitude component and phase component of the radio-frequency signal amplified by the power amplifier 2 or the radio-frequency signal supplied from the RF output terminal 6 to the antenna 7 (output signal), and that comprises a feedback circuit that will reduce the error between the amplitude components of the input signal and output signal, and the error between the phase components of the input signal and output signal.

Incidentally, when the distortion compensating circuit 50 is composed of the polar-loop feedback distortion compensating circuit described above, a configuration is also possible in which the control circuit 51 decides on whether the load impedance detected by the impedance detector 10 belongs to the specific region or not, and causes the polar-loop feedback distortion compensating circuit to operate only when the load impedance belongs to the specific region.

Incidentally, it is to be understood that a free combination of the individual embodiments, variations of any components of the individual embodiments or removal of any components of the individual embodiments are possible within the scope of the present invention.

### INDUSTRIAL APPLICABILITY

The present invention is suitable for a front-end amplifier that amplifies a modulating signal which is the input signal, and that has to prevent the characteristic alterations of the power amplifier or the destruction of the power amplifier when emitting the modulating signal after the amplification into space from an antenna.

### DESCRIPTION OF REFERENCE SYMBOLS

1 RF input terminal; 2 power amplifier; 3, 4 directional coupler (impedance detecting unit); 5 variable-matching circuit; 6 RF output terminal; 7 antenna; 8 output wave detector (impedance detecting unit); 9 reflected wave detector (impedance detecting unit); 10 impedance detector (impedance detecting unit); 11 control circuit (control unit); 12 bias circuit (control unit); 13 DC/DC converter (control unit); 21 instantaneous amplitude detector; 22 peak-hold circuit; 23 bias circuit (control unit); 24 DC/DC converter (control unit); 31 directional coupler (gain detecting unit); 32 mean amplitude detector (gain detecting unit); 33 directional coupler (gain detecting unit); 34 attenuator (gain detecting unit); 35 mean amplitude detector (gain detecting unit); 36 mean gain detecting circuit (gain detecting unit); 37 bias circuit (control unit); 38 variable-gain amplifier; 39 mean gain detecting circuit (gain detecting unit; control unit); 41, 42 instantaneous amplitude detector (gain detecting unit); 43 instantaneous gain detecting circuit (gain detecting unit); 44 bias circuit (control unit); 45 instantaneous gain detecting circuit (gain detecting unit; control unit); 50 distortion compensating circuit; 51 control circuit (control unit) ; 101 RF input terminal; 102 power amplifier; 103 RF output terminal; 104 antenna; 105 bias circuit; 106 DC/DC converter; 107 isolator.

1. A front-end amplifier comprising:
a power amplifier that amplifies a radio-frequency signal which is an input signal, and supplies the radio-frequency signal after amplification to an antenna;
an impedance detecting unit that detects a phase and amplitude of an impedance seen looking into the antenna side from the power amplifier from the radio-frequency signal output from the power amplifier and from a radio-frequency signal reflected from the antenna; and
a control unit that decides on whether the impedance detected by the impedance detecting unit, at least one of phase and amplitude of the impedance, belongs to a specific region which is an area with a preset range or not, and that controls, if the impedance belongs to the specific region, a bias condition of the power amplifier.

2. The front-end amplifier according to claim 1, further comprising:
a variable-matching circuit connected between the power amplifier and the antenna, wherein
the control unit controls, if the impedance detected by the impedance detecting unit belongs to the specific region, an impedance of the variable-matching circuit instead of the bias condition of the power amplifier.

3. The front-end amplifier according to claim 1, further comprising:
a variable-matching circuit connected between the power amplifier and the antenna, wherein
the control unit controls, if the impedance detected by the impedance detecting unit belongs to the specific region, at least one of the bias condition of the power amplifier and an impedance of the variable-matching circuit.

4. The front-end amplifier according to claim 1, wherein
the control unit decides that the impedance belongs to the specific region when the phase of the impedance detected by the impedance detecting unit is within a preset phase range or when the amplitude of the impedance is within a preset amplitude range.

5. (canceled)

6. The front-end amplifier according to claim 2, further comprising:
an instantaneous amplitude detecting circuit that detects instantaneous amplitude of the radio-frequency signal output from the power amplifier; and
a peak-hold circuit that holds a peak voltage of the instantaneous amplitude detected by the instantaneous amplitude detecting circuit for a fixed time period, wherein
the control unit controls the impedance of the variable-matching circuit when the impedance detected by the impedance detecting unit belongs to the specific region, and supplies the power amplifier with a bias voltage that reduces as the peak voltage held by the peak-hold circuit increases, and reversely with the bias voltage that increases as the peak voltage reduces.

7-8. (canceled)

9. The front-end amplifier according to claim 1, further comprising:
a distortion compensating circuit that is connected to an input side of the power amplifier and that compensates for nonlinear distortion occurring in the power amplifier, wherein
the control unit controls, if the impedance detected by the impedance detecting unit belongs to the specific region, a bias condition of the distortion compensating circuit instead of controlling the bias condition of the power amplifier.

10. The front-end amplifier according to claim 9, wherein
the distortion compensating circuit is an analog circuit that comprises a diode or a transistor; and
the control unit controls, if the impedance detected by the impedance detecting unit belongs to the specific region, the bias voltage of the diode or the transistor.

11. The front-end amplifier according to claim 9, wherein
the distortion compensating circuit comprises a polar-loop feedback distortion compensating circuit that will reduce an error between the input signal and the output signal.
